(19) United States
(12) Patent Application Publication
(10) Pub. No.: US 2011/0019828 A1
(43) Pub. Date: Jan. 27, 2011

(54) Apparatus and method for sound enhancer

(76) Inventor: Terry Hung, Fremont, CA (US)

Correspondence Address: Jian Chen, 1200 Pine St, Palo Alto, CA, 94301, US

(21) Appl. No.: 12/460,949

(22) Filed: Jul. 25, 2009

(51) Int. Cl. H03G 5/00; H04R 5/00

(52) U.S. Cl. 381/1; 381/99

(57) ABSTRACT

Apparatuses, methods, and systems directed to enhancing sound quality in audio signal transmissions. Some embodiments of the present invention comprise an audio signal processor operable to boost one or more frequency components of an input signal. In one embodiment, the audio signal processor boosts three frequency components comprising frequency bands centered near 300 Hz, 1.7 kHz, and 5.4 kHz. Other embodiments of the present invention can be used to enhance stereo audio signals comprising a left and a right input signal. The left and the right input signals are filtered and one or more frequency components of the left and the right input signals are boosted by one or more predetermined values. Some embodiments of the present invention comprise one or more integrated circuits comprising one or more analog or digital filters operable to boost one or more frequency components of an audio input signal.

### TECHNICAL FIELD

This invention relates to maintaining the quality of sound in audio signal transmissions.

### BACKGROUND

In audio signal processing, audio signals may be electronically represented in either analog or digital format. Analog audio signal processors operate on the electrical signal; digital audio signal processors operate on the digitized representation of the signal. The loss of fidelity of sound is typical in audio transmissions. Once captured by one or more microphones, the air wave of sound is converted into electronic wave form, i.e., electronic audio signals, either in analog or digital format. Between the source and destination of the transmission of the audio signals, various compressions and decompressions are conducted on the audio signals which may result in the loss of fidelity.

Transparency is the ideal result of audio signal transmissions. In a transparent audio signal transmission, the quality or fidelity of the original sound is maintained and any transmission artifacts are imperceptible. Transparency, however, is subjective. It depends on the listener's hearing abilities, listening conditions, and listening equipment. Although it is difficult to quantify transparency, there are a few statistical methods such as ABX tests that may be used to identify detectable differences in sound quality or fidelity.

Telephone networks and cellular networks are two most widely used audio transmission networks. Audio transmission quality over a wireless cellular network has been improving. However, degradation of sound quality still is noticeable after the audio signal is transmitted through a cellular network. With the development of the Voice over IP (VoIP) technology, audio transmissions over the Internet have been rapidly growing. Services such Skype and Vonage are providing phone services through IP networks. However, many users of VoIP services consider the sound quality as not ideal.

In this and other contexts, a key factor that limits the transparency of sound quality during audio transmissions is the lossy compression techniques. Although digital compression techniques may be able to technically preserve fidelity compared with analog compression techniques, some audiophiles think that the sound quality lacks “warmth” and “depth” after the audio signals are processed by a digital signal processor as compared with an analog signal processor. To improve transparency of an audio signal transmission, certain frequency ranges of the audio signal may be amplified or boosted to compensate the loss of fidelity due to various compression techniques either at the source or at the destination of the audio signal transmission.

### SUMMARY

The present invention provides apparatuses, methods, and systems directed to enhancing sound quality in audio signal transmissions. Some embodiments of the present invention comprise an audio signal processor operatively coupled to an audio input signal and operable to boost one or more frequency components of the input signal. In one embodiment, the audio signal processor boosts three frequency components comprising frequency bands centered near 300 Hz, 1.73 kHz, and 5.4 kHz. Other embodiments of the present invention can be used to enhance stereo audio signals comprising a left and a right input signal. The left and the right input signals are filtered and one or more frequency components of the left and the right input signals are boosted by one or more values. Some embodiments of the present invention comprise one or more integrated circuits comprising one or more analog or digital filters operable to boost one or more frequency components of an audio input signal. In other embodiments, one or more filters may be implemented in the firmware of a device such as a cellular phone or an Internet appliance.

The following detailed description together with the accompanying drawings will provide a better understanding of the nature and advantages of various embodiments of the present invention.

### DESCRIPTION OF THE DRAWINGS

FIG. 1 is a diagram showing an example system architecture for a processor, which processor may be used by an embodiment of the present invention.

FIG. 2 is a diagram showing a flowchart of the example process used for boosting one or more frequency components of an input audio signal, which process may be used by an embodiment of the present invention.

FIG. 3 is a diagram showing an example system architecture for an audio processing apparatus, which apparatus may be used by an embodiment of the present invention.

FIG. 4 is a diagram showing an example system architecture for an audio processing apparatus for stereo audio signals, which apparatus may be used by an embodiment of the present invention.

### DESCRIPTION OF EXAMPLE EMBODIMENT(S)

The following example embodiments and their aspects are described and illustrated in conjunction with apparatuses, methods, and systems which are meant to be illustrative examples, not limiting in scope.

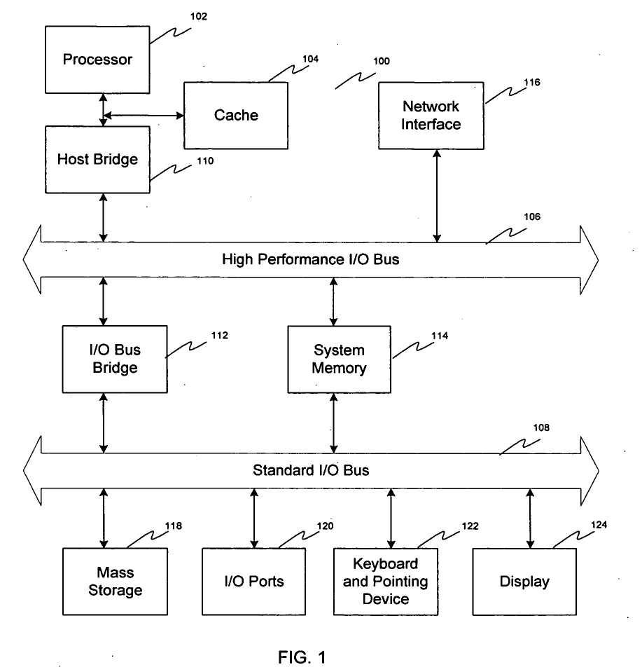

FIG. 1 illustrates, for didactic purposes, a hardware system 100, which may be used to implement a general purpose processor or a digital signal processor. In one embodiment, hardware system 100 comprises a processor 102, a cache memory 104, and one or more software applications and drivers directed to the functions described herein. Additionally, hardware system 100 includes a high performance input/output (I/O) bus 106 and a standard I/O bus 108. A host bridge 110 couples processor 102 to high performance I/O bus 106, whereas I/O bus bridge 112 couples the two buses 106 and 108 to each other. A system memory 114 and a network/communication interface 116 couple to bus 106. Mass storage 118 and I/O ports 110 couple to bus 108. In one embodiment, hardware system 100 may also include a keyboard and pointing device 122 and a display 124 coupled to bus 108. Collectively, these elements are intended to represent a broad category of computer hardware systems, including but not limited to general purpose computer systems based on the x86-compatible processors manufactured by Intel Corporation of Santa Clara, Calif., and the x86-compatible processors manufactured by Advanced Micro Devices (AMD), Inc., of Sunnyvale, Calif., as well as any other suitable processor.

The elements of hardware system 100 are described in greater detail below. In particular, network interface 116 provides communication between hardware system 100 and any of a wide range of networks, such as an Ethernet (e.g., IEEE 802.3) network, etc. Mass storage 118 provides permanent storage for the data and programming instructions, whereas system memory 114 (e.g., DRAM) provides temporary storage for the data and programming instructions when executed by processor 102. I/O ports 110 are one or more serial and/or parallel communication ports that provide communication between additional peripheral devices, which may be coupled to hardware system 100.

Hardware system 100 may include a variety of system architectures; and various components of hardware system 100 may be rearranged. For example, cache 104 may be on-chip with processor 102. Alternatively, cache 104 and processor 102 may be packed together as a “processor module,” with processor 102 being referred to as the “processor core.” In some embodiments, processor 102 may be referred to as Digital Signal Processor (DSP). Furthermore, certain embodiments of the present invention may not require nor include all of the above components. For example, the peripheral devices shown coupled to standard I/O bus 108 may couple to high performance I/O bus 106. In addition, in some embodiments only a single bus may exist with the components of hardware system 100 being coupled to the single bus. Furthermore, hardware system 100 may include additional components, such as additional processors, storage devices, I/O devices, or memories.

In one embodiment, the sound enhancer described herein are implemented as a series of software routines run by hardware system 100. These software routines comprise a plurality or series of instructions to be executed by a processor in a hardware system, such as processor 102. Initially, the series of instructions are stored on a storage device, such as mass storage 118. However, the series of instructions can be stored on any suitable storage medium, such as a diskette, CD-ROM, ROM, EEPROM, etc. Furthermore, the series of instructions need not be stored locally, and could be received from a remote storage device, such as a server on a network, via network/communication interface 116. The instructions are copied from the storage device, such as mass storage 118, into memory 114 and then accessed and executed by processor 102.

An operating system manages and controls the operation of hardware system 100, including the input and output of data to and from software applications (not shown). The operating system provides an interface between the software applications being executed on the system and the hardware components of the system. According to one embodiment of the present invention, the operating system is the LINUX operating system. However, the present invention may be used with other suitable operating systems, such as the Windows® 95/98/NT/XP/Vista/Mobile operating system, available from Microsoft Corporation of Redmond, Wash., the Apple Macintosh Operating System, available from Apple Computer Inc. of Cupertino, Calif., the Android Operating System, available from Google Inc. of Mountain View, Calif., and the like.

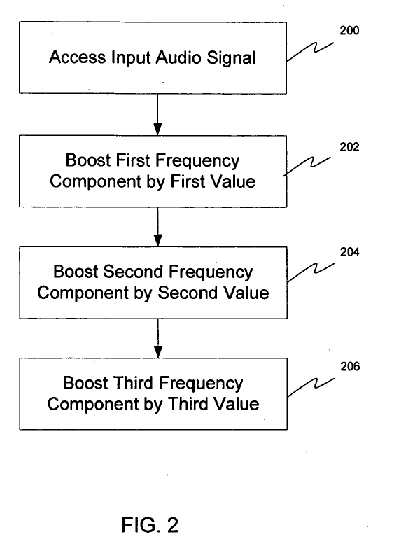

FIG. 2 illustrates an example process used to enhance sound quality, which process may be used by an embodiment of the present invention. In the first step 200, the embodiment accesses the input audio signal. In some embodiments, the input audio signal may be in digital format. In other embodiments, the input audio signal may be in analog format. The input audio signal comprises various frequency components. Certain frequency components may be amplified or boosted to enhance transparency. In step 202, the embodiment boosts a frequency within a band from about 100 Hz to 500 Hz by a value in the range of about 1 dB to about 6 dB. In one particular embodiment, the frequency at 300 Hz is amplified by 1 dB. In step 204, the audio signal is further boosted at a frequency within a band from 1 kHz to about 2.5 kHz by a value in the range of about 1 dB to about 6 dB. In one particular embodiment, the frequency at 1.7 kHz is boost by 2 dB. In step 206, the audio signal is again boosted at a frequency within a band from about 4.4 kHz to about 6.4 kHz by a value in the range of about 1 dB to about 6 dB. In one particular embodiment, the frequency at 5.4 kHz is boosted by 1 dB.

In some embodiments, the audio signal may be boost at three frequencies centered around 300 Hz, 1.7 kHz, and 5.4 kHz by a value of about 2 dB, about 4 dB, and about 2 dB, respectively. The boost or amplification may be performed at the source of the audio transmission or at the destination of the audio transmission. In some embodiments, the three boost values are kept at a ratio of 1:2:1, i.e., the ratio of the boost value near the frequency at 300 Hz to the boost value near the frequency at 1.7 kHz is 1½, and the ratio of the boost value near the frequency at 1.7 kHz to the boost value near the frequency at 5.4 kHz is 2.

In some embodiments, the example process in FIG. 2 may be implemented in an analog circuit. Step 202 may be implemented as an analog filter in the analog circuit. Similarly, step 204 and step 206 may be implemented as analog filters as well. The three filters boost the frequencies centered around 300 Hz, 1.7 kHz, and 5.4 kHz by a value in the range of about 1 to about 6 dB, respectively.

In other embodiments, the example process in FIG. 2 may be implemented in a digital circuit. Step 202 may be implemented as a digital filter in the digital circuit. Similarly, step 204 and step 206 may be implemented as digital filters as well. The three filters boost the frequencies centered around 300 Hz, 1.7 kHz, and 5.4 kHz by a value in the range of about 1 to about 6 dB, respectively.

In some other embodiments, the example process in FIG. 2 may be implemented in a mixed analog digital circuit. Step 202, step 204, and step 206 may be implemented as analog filters, digital filters, or a combination of analog and digital filters. In yet other embodiments, the example process in FIG. 2 may be implemented as a software routine in a general purpose processor or a digital signal processor. The input signal may be boosted by the software routine at the frequencies centered around 300 Hz, 1.7 kHz, and 5.4 kHz by a value in the range of about 1 to about 6 dB, respectively. In some embodiments, the software routine may be embedded in a firmware of a device such as a cellular phone. In other embodiments, the software routine may be used in a codec either during coding or during decoding of the audio signal to boost the three frequency bands.

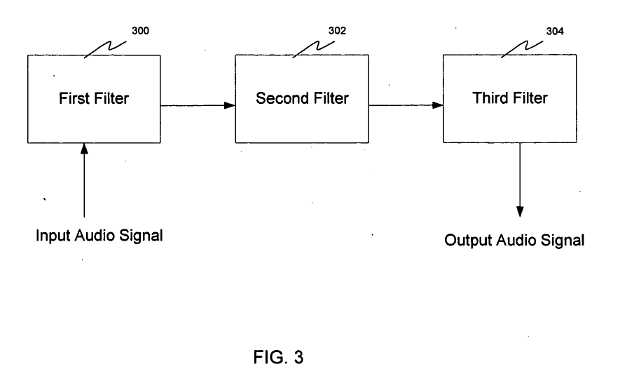

FIG. 3 illustrates an example audio signal processor used to enhance sound quality, which system may be used by an embodiment of the present invention. The first filter 300 is operatively coupled to an input audio signal and is operable to boost a frequency within a band from about 100 Hz to 500 Hz by a value in the range of about 1 dB to about 6 dB. In one particular embodiment, the frequency at 300 Hz is amplified by 1 dB. The second filter 302 is operatively coupled to the input signal boosted by the first filter 300 and is operable to further boost the input signal at a frequency within a band from 1 kHz to 2.5 kHz by a value in the range of about 1 dB to about 6 dB. In one particular embodiment, the frequency at 1.7 kHz is boost by 2 dB. The third filter 304 is operatively coupled to the input signal boosted by the first and the second filters and is operable to further boost the input signal at a frequency within a band from about 4.4 kHz to about 6.4 kHz by a value in the range of about 1 dB to about 6 dB. In one particular embodiment, the frequency at 5.4 kHz is boosted by 1 dB.

In some embodiments, the example audio signal processor in FIG. 3 may be implemented as a circuit board and may be plugged into a computer via an interface such as the PCI bus interface. In other embodiments, the example audio signal processor in FIG. 3 may be implemented as a custom integrated circuit chip and may be used in computers or cellular phones.

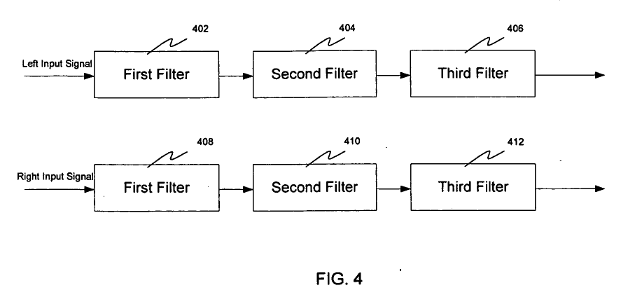

FIG. 4 illustrates an example audio signal processor used to enhance stereo audio input signals, which processor may be used by an embodiment of the present invention. A stereo audio signal comprises a left input signal and a right input signal. In some embodiments, the left input signal passes through the first filter 402 and a frequency within the frequency band from about 100 Hz to about 500 Hz is boosted by a value within the range of about 1 dB to about 6 dB. The boosted left signal then passes through the second filter 404 and a frequency within the frequency band from about 1 kHz to about 2.5 kHz is boosted by a value within the range of about 1 dB to about 6 dB. The signal is further boosted by a third filter 406 at a frequency within the frequency band from about 4.4 kHz to about 6.4 kHz by a value within the range of about 1 dB to about 6 dB. Similarly, the right input signal is filtered by a filter 408 and a frequency within the frequency band from about 100 Hz to about 500 Hz is boosted by a value within the range of about 1 dB to about 6 dB. The right input signal is then filtered by filter 410 and a frequency within the frequency band from about 1 kHz to about 2.5 kHz is boosted by a value within the range of about 1 dB to about 6 dB. The right input signal is further filtered by filter 412 which boosts a frequency within the frequency band from about 4.4 kHz to about 6.4 kHz by a value within the range of about 1 dB to about 6 dB. In some embodiments, the filters 402 and 408 may be the same, the filters 404 and 410 may be the same, and the filters 406 and 412 may be the same. In other embodiments, the filters 402 and 408 may boost the input signal at a different frequency within the band from about 100 Hz to bout 500 Hz. The filters 404 and 410 may boost the input signal at a different frequency within the band from about 1 kHz to about 2.5 kHz. The filters 406 and 412 may boost the input signal at different frequencies within the band from about 4.4 kHz to about 6.4 kHz. In yet other embodiments, the filter 402 and 408 may boost the input signal at the same frequency, but by different values within the range of about 1 dB to about 6 dB. Similarly, the filter 404 and 410, and the filters 406 and 412 may boost the input signal at the same frequency, but by different values ranging from about 1 dB to about 6 dB. In some embodiments, to optimize transparency, the boost values by the filters 402, 404, and 406 are kept at a ratio of 1:2:1, and the boost values by the filters 408, 410, and 412 are kept at a ratio of 1:2:1. In one embodiment, the left and right input signals of a stereo audio signal are filtered at the source of the audio transmission. In other embodiments, the stereo audio signal is filtered by filters 402, 404, 406, 408, 410, and 412 at the destination of the audio transmission. In yet other embodiments, the left and the right input signals may be filtered at both the source and the destination of the audio transmission.

The present invention has been explained with reference to specific embodiments. For example, while embodiments of the present invention have been described with reference to specific material, hardware and/or software components, those skilled in the art will appreciate that different combinations of material, hardware and/or software components may also be used. Other embodiments will be evident to those of ordinary skill in the art. It is therefore not intended that the present invention be limited, except as indicated by the appended claims.

What is claimed is:

1. An audio signal processor comprising
a first filter operatively coupled to an input signal and operable to boost a first frequency component of the input signal by a first value, wherein the first frequency component comprises a frequency band from about 100 Hz to about 500 Hz;
a second filter operatively coupled to the boosted input signal and operable to boost a second frequency component of the input signal by a second value, wherein the second frequency component comprises a frequency band from about 1 kHz to about 2.5 kHz; and
a third filter operatively coupled to the input signal boosted by the first and the second filters wherein the third filter is operable to boost a third frequency component by a third value, and wherein the third frequency component comprises a frequency band from about 4.4 kHz to about 6.4 kHz.

2. The audio signal processor of claim 1, wherein the first value is between about 1 dB and about 6 dB, the second value is between about 1 dB and about 6 dB, and the third value is between about 1 dB and about 6 dB.

3. The audio signal processor of claim 1, wherein the ratio of the second value to the first value is about 2, and the ratio of the second value to the third value is about 2.

4. The audio signal processor of claim 1, wherein each filter comprises one or more analog circuits.

5. The audio signal processor of claim 1, wherein each filter comprises one or more digital circuits.

6. An audio signal processing apparatus operative upon a stereo audio signal comprising a left input signal and a right input signal, said apparatus comprising:
a left enhancement circuit receiving the left input signal and modifying the left input signal to boost one or more frequency components; and
a right enhancement circuit receiving the right input signal and modifying the right input signal to boost one or more frequency components;
wherein each enhancement circuit comprising:
a first filter operable to boost a first frequency component of the input signal by a first value, wherein the first frequency component comprises a frequency band from about 100 Hz to about 500 Hz;
a second filter operable to boost a second frequency component of the input signal by a second value, wherein the second frequency component comprises a frequency band from about 1 kHz to about 2.5 kHz; and
a third filter operable to boost a third frequency component by a third value, and wherein the third frequency component comprises a frequency band from about 4.4 kHz to about 6.4 kHz.

7. The audio signal processing apparatus of claim 6, wherein the first value is between about 1 dB and about 6 dB, the second value is between about 1 dB and about 6 dB, and the third value is between about 1 dB and about 6 dB.

8. The audio signal processing apparatus of claim 6, wherein the ratio of the second value to the first value is about 2, and the ratio of the second value to the third value is about 2.

9. The audio signal processing apparatus of claim 6, wherein each enhancement circuit comprises one or more analog circuits.

10. The audio signal processing apparatus of claim 6, wherein each enhancement circuit comprises one or more digital circuits.

11. A method for audio signal processing comprising
filtering an input signal in a first filter to boost a first frequency component by a first value, wherein the first frequency component comprises a frequency band centered near 300 Hz;
filtering the filtered input signal in a second filter to boost a second frequency component by a second value, wherein the second frequency component comprises a frequency band centered near 1.7 kHz; and
filtering the input signal filtered by the second filter in a third filter to boost a third frequency component by a third value, wherein the third frequency component comprises a frequency band centered near 5.4 kHz.

12. The method of claim 11, wherein the first value is between about 1 dB to about 6 dB, the second value is between about 1 dB and about 6 dB, and the third value is between about 1 dB and about 6 dB.

13. The method of claim 11, wherein the ratio of the second value to the first value is about 2, and the ratio of the second value to the third value is about 2.

14. A computer-readable medium tangibly embodying computer program code, the computer program code when executed by a computer performing a method comprising:
accessing an audio input signal;
filtering the input signal in a first filter to boost a first frequency component by a first value, wherein the first frequency component comprises a frequency band centered near 300 Hz;
filtering the filtered input signal in a second filter to boost a second frequency component by a second value, wherein the second frequency component comprises a frequency band centered near 1.7 kHz; and
filtering the input signal filtered by the second filter in a third filter to boost a third frequency component by a third value, wherein the third frequency component comprises a frequency band centered near 5.4 kHz.

15. The computer-readable medium of claim 14, wherein the first value is between about 1 dB to about 6 dB, the second value is between about 1 dB and about 6 dB, and the third value is between about 1 dB and about 6 dB.

16. The computer-readable medium of claim 14, wherein the ratio of the second value to the first value is about 2, and the ratio of the second value to the third value is about 2.

17. A computer program product comprising a computer-readable medium with computer program logic tangibly recorded thereon, the computer program product comprising:
means for accessing an input audio signal;
means for filtering the input signal in a first filter to boost a first frequency component by a first value;
means for filtering the filtered input signal in a second filter to boost a second frequency component by a second value; and
means for filtering the input signal filtered by the second filter in a third filter to boost a third frequency component by a third value.

18. A method for audio signal processing comprising
filtering an input signal in a first filter to boost a first frequency component by a first value, wherein the first frequency component comprises a frequency band from about 100 Hz to about 500 Hz; and
filtering the filtered input signal in a second filter to boost a second frequency component by a second value, wherein the second frequency component comprises a frequency band from about 4.4 kHz to about 6.4 kHz.

19. The method of claim 18, wherein the first value is between about 1 dB to about 6 dB and the second value is between about 1 dB and about 6 dB.

20. A method for audio signal processing comprising
filtering an input signal in a first filter to boost a first frequency component by a first value, wherein the first frequency component comprises a frequency band from about 100 Hz to about 500 Hz; and
filtering the filtered input signal in a second filter to boost a second frequency component by a second value, wherein the second frequency component comprises a frequency band from about 1 kHz to about 2.5 kHz.

21. The method of claim 20, wherein the first value is between about 1 dB to about 6 dB and the second value is between about 1 dB and about 6 dB.
